(19) United States
(12) Patent Application Publication
(10) Pub. No.: US 2015/0110291 A1
(43) Pub. Date: Apr. 23, 2015

(54) Differential High Impedance Apparatus

(71) Applicant: Knowles Electronics LLC, Itasca, IL (US)

(72) Inventors: Claus Erdmann Furst, Roskilde (DK); John Nielsen, Hillerod (DK)

(21) Appl. No.: 14/512,858

(22) Filed: Oct. 13, 2014

Related U.S. Application Data
(60) Provisional application No. 61/892,153, filed on Oct. 17, 2013.

(51) Int. Cl. H04R 3/04; H04R 1/08; H03F 3/45

(52) U.S. Cl. CPC H04R 3/04; H03F 3/45179; H04R 1/08; H03F 2200/144
USPC 381/98

(57) ABSTRACT

A differential high impedance circuit for use in an acoustic apparatus includes a first set of transistor devices and a second set of transistor devices. The first set of transistor devices includes a first transistor (302) and a second transistor (306), and the first transistor (302) coupled to Vdd and the second transistor (306) coupled ground. The second set of two transistor devices includes a third transistor (304) and a fourth transistor (308). The third transistor (304) is coupled to the first transistor (302) and provides a first output (Out+), and the fourth transistor (308) is coupled to the second transistor (306) and provides a second output (Out−). The first and second outputs configured to provide a resistance.

### CROSS REFERENCE TO RELATED APPLICATION

This patent claims benefit under 35 U.S.C. §119 (e) to United States Provisional Application No. 61892153 entitled “Differential High Impedance Apparatus” filed Oct. 17, 2013, the content of which is incorporated herein by reference in its entirety.

### TECHNICAL FIELD

This application relates to microphones and, more specifically, to the impedance elements of microphones.

### BACKGROUND OF THE INVENTION

Micro-Electro-Mechanical System (MEMS) microphones are typically composed of two main components: a MEMS device that receives and converts sound energy into an electrical signal, and an Application Specific Integrated Circuit (ASIC) (or other circuits such as buffers, amplifiers, and analog-to-digital converters). These devices often take the electrical signal from the MEMS device and performs post-processing on the signal and/or buffering the signal for the following circuit stages in a larger electronic environment.

Integrated circuits for audio applications utilize devices with time constants in the approximately 0.01 to 10 second range. This can either be implemented using large valued capacitors or large valued resistors.

Resistors in integrated circuit processes are normally practically limited to approximately 1-10 M ohms. This is due to be fact that resistors typically are implemented using high resistive poly silicon which has a resistivity of 1-10 k Ohm pr square, e.g., a resistor element 2 um wide and 2 um long. Capacitors larger than 100 pF are also not feasible to implement.

Consequently, large resistors occupy large areas and the same is true for on chip capacitors where the representative values are 1-2 fF/sq um. Capacitors cannot be made much bigger than 100-200 pF.

Previous approaches have not adequately provided small resistors that did not have some type of performance problems. This has led to some user dissatisfaction with these previous approaches.

### BRIEF DESCRIPTION OF THE DRAWINGS

For a more complete understanding of the disclosure, reference should be made to the following detailed description and accompanying drawings wherein:

FIG. 1 comprises a block diagram of a microphone that utilizes a differential high impedance element according to various embodiments of the present invention;

FIG. 2 comprises a block diagram of a differential amplifier that utilizes a differential high impedance element according to various embodiments of the present invention;

FIG. 3 comprises a circuit diagram of a high impedance differential apparatus according to various embodiments of the present invention;

FIG. 4 shows a chart of the operating regions of the circuit of FIG. 3 according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Approaches are described herein that provide a differential high impedance apparatus or circuit. In one example, four complementary CMOS devices are used including one set (two devices) of NMOS devices and one set (two devices) of PMOS devices. Both sets of transistors are scaled by a factor of M and biased by Ibias+ and Ibias− current sources. A reference voltage generator biases the differential circuit above ground (GND). When one of the pairs of transistors starts to conduct and becomes low impendence, then the other pair is still of high impendence. In one aspect, the circuit operates when biased centered around VDD/2 (or at least not close to either VDD or GND) as parasitic (bulk) diodes will start to conduct.

The circuits provided herein can be combined with a fully differential analog circuit, e.g. amplifier, to operate. In this example, the amplifier operates at DC levels close to approximately VDD/2.

In many of these embodiments, a differential high impedance circuit for use in an acoustic apparatus includes a first set of transistor devices including a first transistor and a second transistor; and a second set of two transistor devices including a third transistor and a fourth transistor. The third transistor is coupled to the first transistor and provides a first output, and the fourth transistor is coupled to the second transistor and provides a second output. The first and second outputs are configured to provide a resistance.

Each of the first transistor and the second transistor are selectively actuated to conduct and such that the third transistor and fourth transistor are alternatively actuated to conduct or de-actuated to weakly conduct. The actuation and de-actuation of the third transistor and the fourth transistor is effective to provide a high resistance that is substantially constant over time.

In other aspects, selected ones of the first transistor, second transistor, third transistor, and fourth transistor are NMOS devices. In some other aspects, selected ones of the first transistor, second transistor, third transistor, and fourth transistor are PMOS devices.

In some examples and when any of the first transistor, second transistor, third transistor, or fourth transistor conduct, the resistance is in the kilo ohm range. In other examples and when any of the first transistor, second transistor, third transistor, or fourth transistor do not conduct, the resistance is in the giga ohm range.

In other aspects, the differential high impedance circuit is disposed in a differential amplifier. In still other aspects, the differential amplifier is disposed on an application specific integrated circuit (ASIC). The ASIC may include a micro-electro-mechanical system (MEMS) element.

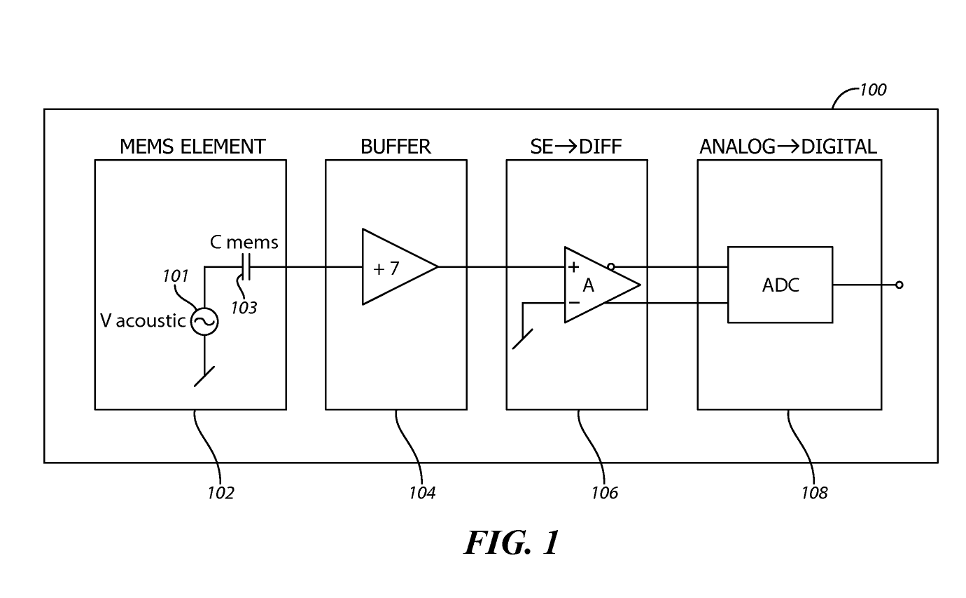

Referring now to FIG. 1, one example of a digital Microelectromechanical system (MEMS) microphone 100 is shown. The microphone 100 includes a MEMS device 102, a buffer 104, a differential amplifier 106, and an analog-to-digital converter 108.

The MEMS device 102 is any type of MEMS microphone device that converts sound energy 101 (represented by Vacoustic) into an analog electrical signal. The MEMS device 102 may also include a diaphragm and back plate that form a capacitance 103 that varies with the acoustic energy received to produce an analog electrical signal. The analog electrical signal is fed to the buffer 104, which buffers the signal for later processing. The analog signal is then fed from the buffer to the differential amplifier 106.

The differential amplifier 106 provides a differential resistance that is used by various components including the analog-to-digital converter 108. Because of the approaches described herein, the physical size of this element is small, but the amount of the resistance it provides is large. Because it can supply such a large resistance, it can be utilized with other circuits that need or utilize large resistances in their operation. The analog-to-digital converter 108 converts the analog signal (received from the differential amplifier 106 to a digital signal.

The digital signal can be transmitted to other electronic circuits outside the microphone 100. In these regards, it will be appreciated that the microphone 100 can be disposed in another device such as a cellular phone or a personal computer. Other examples are possible. The elements of the microphone 100 can be disposed on one or more printed circuit boards, housings, or other assemblies.

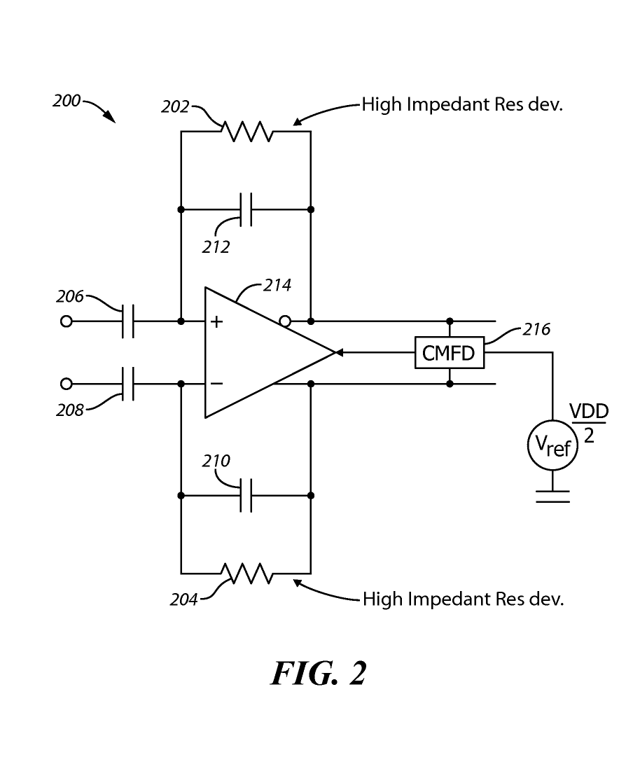

Referring now to FIG. 2, one example of the differential amplifier 200 (e.g., the differential amplifier 106 in FIG. 1) is described. The function of the differential amplifier 200 is to amplify the signal and convert it from single-ended signal to a differential signal.

The amplifier 200 includes a first high resistance impedance 202, a second high resistance impedance 204, a first capacitor 206, a second capacitor 208, a third capacitor 210, a fourth capacitor 212, a operational amplifier 214, and a common mode feedback block (CMFB) block 216. The common mode feedback block 216 assures that the common mode voltage of the differential amplifier is biased close to VDD/2. This is to assure that the amplifier can deliver the largest possible signal swing at the output.

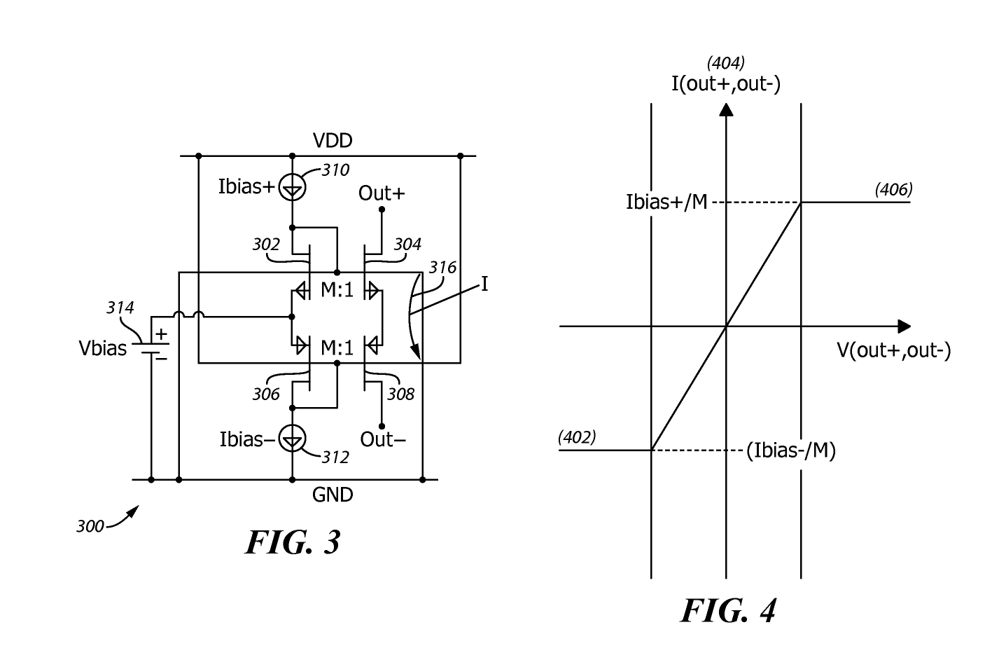

The first high resistance impedance 202 and the second high resistance impedance 204 provide high impedances as described below with respect to FIG. 3 and FIG. 4.

The functions of the first capacitor 206, second capacitor 208, third capacitor 210, and fourth capacitor 212 are to set the differential gain of the amplifier. The function of the operational amplifier 214 is to provide high differential open loop gain so that the gain set by the gain capacitors is precisely defined.

Referring now to FIG. 3 and FIG. 4, one example of a differential high impedance element 300 (such as elements 202 and 204 in FIG. 2) are shown. The element 300 includes a first NMOS transistor device 302, a second NMOS transistor device 304, a first PMOS transistor device 306, and a second PMOS transistor device 308. The internal structure and operation of the devices 302, 304, 306, and 308 are well known to those skilled in the art and will be discussed to further here.

The circuit also includes a first current source 310 and a second current source 312. A bias voltage 314 is applied to the sources of transistors 302 and 306 and thereby biases the differential circuit above ground. An output voltage is presented between Out+and Out−.

Both sets of transistors (transistors 302/306 and 304/308) are scaled by a factor of M (e.g., M=1) and biased by Ibias+ and Ibias current sources 310 and 312. By “scaling,” it is meant that similar or identical devices are connected in parallel.

As shown in FIG. 4, the circuit of FIG. 3 operates in three regions. Different voltages are applied across the output voltage (between OUT+ and OUT− in FIG. 3) to produce different currents and thereby different resistances . In this respect, a current 316 (I) flowing through transistors 304 and 308 varies between +/−Ibias/M as shown in FIG. 3. In each of the regions, a small signal equivalent resistor value can be calculated, i.e., for small variations of voltage across output of the circuit the current will approximately vary linearly. The result is that the circuit will behave as a resistor. This is what is referred to as the equivalent resistor. The resistor value will vary across the three regions as described earlier.

In a first region 402, the transistor 304 is low impedance (conducting) and transistor 308 is high impedance (weakly conducting). In a second region 404, the transistor 304 and the transistor 308 are both high impedance (both weakly conducting). In the third region 406, the transistor 304 is high impedance (weakly conducting), and the transistor 308 is low impedance (conducting). In all regions, the transistor 302 and the transistor 306 are activated (conducting). By “low impedance,” it is meant that the equivalent resistor is in the range of Kilo ohms. By “high impedance,” it is meant that the equivalent resistor is in the range of Giga ohms.

In all regions, the output resistance across the circuit is high impedance and varies relatively little within each region, e.g., one decade. This contrasts with previous approaches where the impedance could vary many decades over the whole operation range. For example, some approaches had regions where devices started to conduct and the impedance dropped dramatically and in a non-linear way by many decades.

Because of the approaches described herein, the physical size of this element is small, but the amount of the resistance it provides is large. Because it can supply such a large resistance, it can be utilized with other circuits that need large resistances to operate.

Preferred embodiments of this invention are described herein, including the best mode known to the inventors for carrying out the invention. It should be understood that the illustrated embodiments are exemplary only, and should not be taken as limiting the scope of the invention.

What is claimed is:

1. A differential high impedance circuit for use in an acoustic apparatus, the circuit comprising:
a first set of transistor devices including a first transistor and a second transistor;
a second set of two transistor devices including a third transistor and a fourth transistor, the third transistor coupled to the first transistor and providing a first output, the fourth transistor coupled to the second transistor and providing a second output, the first and second outputs configured to provide a resistance;
such that each of first transistor and second transistor are selectively actuated to conduct and such that the third transistor and fourth transistor are alternatively actuated to conduct or de-actuated to weakly conduct, the actuation and de-actuation of the third transistor and the fourth transistor effective to provide a high resistance that is substantially constant over time.

2. The differential high impedance circuit of claim 1, wherein selected ones of the first transistor, second transistor, third transistor, and fourth transistor are NMOS devices.

3. The differential high impedance circuit of claim 1, wherein selected ones of the first transistor, second transistor, third transistor, and fourth transistor are PMOS devices.

4. The differential high impedance circuit of claim 1, wherein when any of the first transistor, second transistor, third transistor, or fourth transistor conduct, the resistance is in the kilo ohm range.

5. The differential high impedance circuit of claim 1, wherein when any of the first transistor, second transistor, third transistor, or fourth transistor do not conduct, the resistance is in the giga ohm range.

6. The differential high impedance circuit of claim 1, wherein the differential high impedance circuit is disposed in a differential amplifier.

7. The differential high impedance circuit of claim 6, wherein the differential amplifier is disposed on an application specific integrated circuit (ASIC).

8. The differential high impedance circuit of claim 7, wherein the ASIC includes a micro-electro-mechanical system (MEMS) element.
